(19) United States
(12) Patent Application Publication
(10) Pub. No.: US 2007/0019696 A1
(43) Pub. Date: Jan. 25, 2007

(54) Vertical cavity surface emitting laser and method for fabricating the same

(76) Inventors: Li-Hung Lai, Hsinchu City (TW); Li-Wen Lai, Hsinchu City (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/186,764

(22) Filed: Jul. 22, 2005

(51) Int. Cl. H01S 5/00

(52) U.S. Cl. 372/46.01; 372/45.01; 372/46.013; 372/46.015

(57) ABSTRACT

The invention relates to a vertical cavity surface emitting laser and method for fabricating the same. The vertical cavity surface emitting laser of the invention comprises: a substrate, a first reflector, an active layer, a second reflector, a first electrode layer and a second electrode layer. The second reflector has a first confinement layer with a first aperture and a second confinement layer with a second aperture. The second aperture is smaller than the first aperture. According to the invention, because the second confinement layer is formed by implanting oxygen ion into the second reflector and heating to let the oxygen ion and Al content in the second reflector react to form an oxide layer, the second confinement layer can be used as an optical and electronic confinement layer. Therefore, the width and depth of the second confinement layer can be achieved precisely and easily.

### BACKGROUND OF TH INVENTION

1. Field of the Invention

The present invention relates to a vertical cavity surface emitting laser and method for fabricating the same, more particularly, a vertical cavity surface emitting laser with high yield rate and controllable process.

2. Description of the Related Art

Referring to FIG. 1, the conventional vertical cavity surface emitting laser 10 comprises: a substrate 11, a first reflector 12, an active layer 13, a second reflector 14, a contact layer 15, a first electrode layer 16 and a second electrode layer 17. The substrate 11 has a first surface and a second surface. The first reflector 12 is formed on the first surface of the substrate 11. The active layer 13 is formed on the first reflector 12. The second reflector 14 is formed on the active layer 13. The contact layer 15 is formed on the second reflector 14. The first electrode layer 16 is formed on the contact layer 15. The second electrode layer 17 is formed on the second surface of the substrate 11.

The second reflector 14 comprises a current confinement layer 141 formed in the second reflector 14. The current confinement layer 141 has an aperture. In the vertical cavity surface emitting laser 10, because the area of the active layer 15 as an emitting area is small, the input current must be confined in the aperture of the second reflector 14 to obtain the higher current density. The conventional methods for forming the current confinement layer 141 are the hydrogen ion implanting process and the high temperature and wet oxidized process. The hydrogen ion implanting process utilizes the ion implanter with high energy to implant hydrogen ion into the second reflector 14 to form the current confinement layer 141. The high temperature and wet oxidized process oxidizes Al material to form the current confinement layer. The current confinement layer manufactured by the high temperature and wet oxidized process has better optical and electronic confinement effect. However, owing to the high temperature vapor during the manufacture, the stability and the yield rate of the vertical cavity surface emitting laser manufactured by the high temperature and wet oxidized process is not good, and it is particularly difficult to form a small aperture in the current confinement layer utilizing the high temperature and wet oxidized process.

Therefore, it is necessary to provide a vertical cavity surface emitting laser and method for fabricating the same so as to solve the above problem.

### SUMMARY OF THE INVENTION

One objective of the present invention is to provide a vertical cavity surface emitting laser. The vertical cavity surface emitting laser comprises: a substrate, a first reflector, an active layer, a second reflector, a first electrode layer and a second electrode layer. The substrate has a first surface and a second surface. The first reflector is formed on the first surface of the substrate. The active layer is formed on the first reflector. The second reflector is formed on the active layer. The second reflector has a first confinement layer and a second confinement layer. The first confinement layer has a first aperture, and the second confinement layer has a second aperture. The second aperture is smaller than the first aperture. The first electrode layer is formed on the second reflector. The second electrode layer is formed on the second surface of the substrate.

Another objective of the present invention is to provide a method for fabricating a vertical cavity surface emitting laser, comprising the steps of: (a) providing a substrate, the substrate having a first surface and a second surface; (b) forming a first reflector on the first surface of the substrate; (c) forming an active layer on the first reflector; (d) forming a second reflector on the active layer; (e) forming a first confinement layer in the second reflector, the first confinement layer having a first aperture; (f) forming a second confinement layer in the second reflector, the second confinement layer having a second aperture, the second aperture being smaller than the first aperture; (g) forming a first electrode layer on the second reflector; and (h) forming a second electrode layer on the second surface of the substrate.

According to the invention, because the second confinement layer is formed by implanting oxygen ion into the second reflector and heating to let the oxygen ion and Al content in the second reflector react to form an oxide layer, the second confinement layer can be used as an optical and electronic confinement layer. Therefore, the width and depth of the second confinement layer can be achieved precisely and easily.

### BRIEF DESCRIPTION OF THE DRAWINGS

FIG. 1 shows a conventional vertical cavity surface emitting laser.

FIG. 2 shows a vertical cavity surface emitting laser, according to the invention.

FIG. 3 shows a top plan view of the vertical cavity surface emitting laser, according to the invention.

FIGS. 4A to 4C illustrate the manufacturing method of the vertical cavity surface emitting laser, according to the invention.

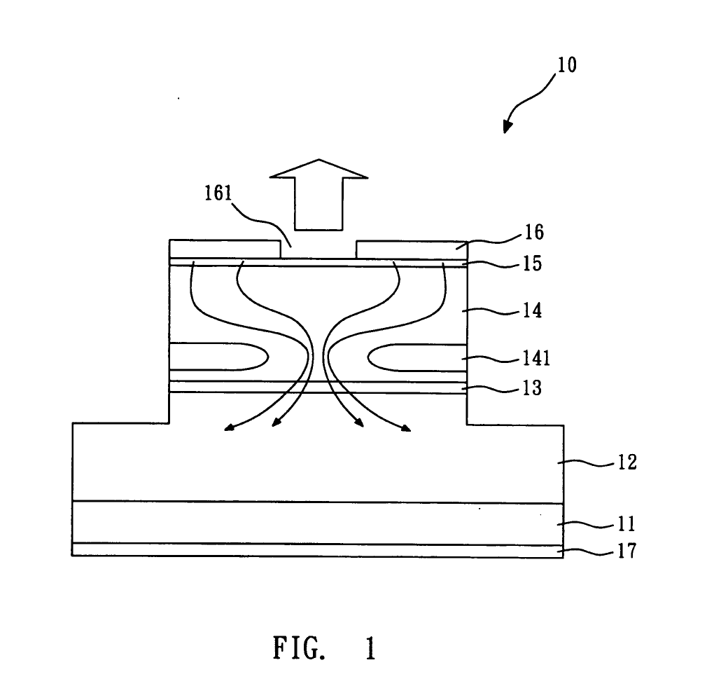

### DETAILED DESCRIPTION OF THE INVENTION

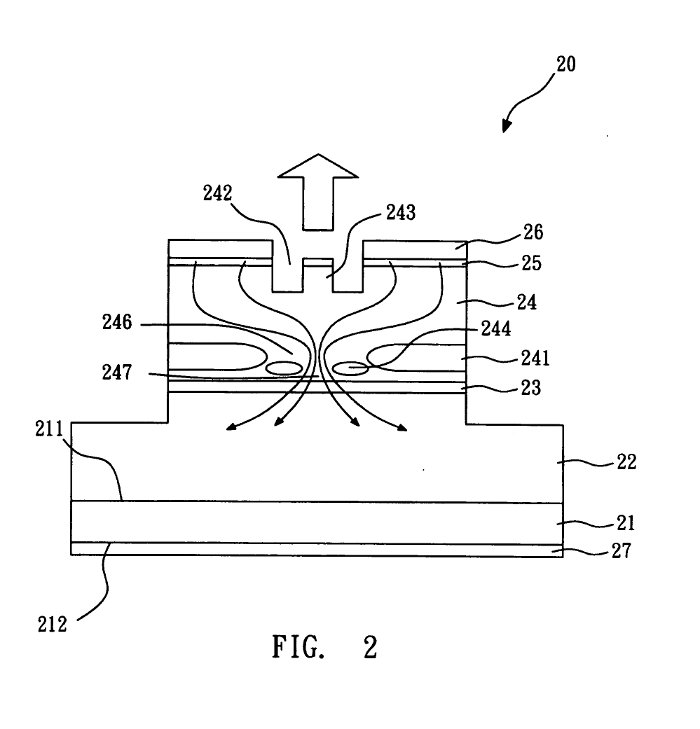

Referring to FIG. 2, according to the invention, a vertical cavity surface emitting laser 20 comprises: a substrate 21, a first reflector 22, an active layer 23, a second reflector 24, a first electrode layer 26 and a second electrode layer 27. The substrate 21 may be an n⁺-type GaAs or InP substrate. The substrate 21 has a first surface 211 and a second surface 212. The first reflector 22 is formed on the first surface 211 of the substrate 21. The first reflector 22 is a distributed Bragg reflector (DBR) with many pairs of layers. Each pair of layers is formed as a graded Si-doped n⁺-type AlₓGa₍₁₋ₓ₎As/AlAs structure, wherein x changes from 0.12 to 1, and 1-x changes from 0.88 to zero.

The active layer 23 is formed on the first reflector 22. The active layer 23 comprises a plurality of quantum wells with non-doped GaAs and Al_{y}GaAs, wherein y changes from 0.3 to 0.6. The second reflector 24 is formed on the active layer 23. The second reflector 24 is a distributed Bragg reflector (DBR) with many pairs of layers. Each pair of layers is formed as a graded Zn-doped or C-doped p⁺-type Al_{z}Ga_{(1-z)}As/AlAs structure, wherein z changes from 1 to 0.12, and 1-x changes from zero to 0.88.

The active layer 23 is used to generate light radiation beam. The first reflector 22 and second reflector 24 are used to reflect light radiation beam. The second reflector 24 is utilized to pass through laser beam. The second reflector 24 has a first confinement layer 241 and a second confinement layer 244. The first confinement layer 241 has a first aperture 246, and the second confinement layer 244 has a second aperture 247. The second aperture 247 is smaller than the first aperture 246. The second confinement layer 244 can be used as an optical and electronic confinement layer. The width and depth of the second confinement layer 244 can be achieved precisely and easily. Therefore, the size of the second aperture 247 can be controlled precisely so as to control the current passed through the second aperture 247.

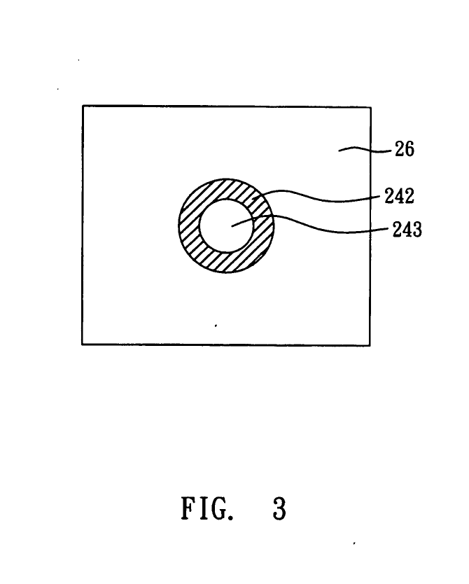

The second reflector 24 further comprises a slot 242 corresponding to the shape of the second confinement layer 244. Referring to FIG. 3, the slot 242 is formed into a circular shape. The slot 242 is not limited to the circular shape, and may be quadrate shape or other shapes. The slot 242 is used to easily form the second reflector 24.

Referring to FIG. 2 again, the vertical cavity surface emitting laser 20 of the invention further comprises a contact layer 25 formed on the second reflector 24. The contact layer 25 is a high C-doped GaAs layer, and used to electrically contact the first electrode layer 26. The first electrode layer 26 is formed on the contact reflector 25. The first electrode layer 26 comprises an opening corresponding to the slot 242. The second electrode layer 27 is formed on the second surface 212 of the substrate 21. The first electrode layer 26 and the second electrode layer 27 are connected to a power supply so as to form a driving current path. The direction of the driving current is parallel to the direction of the laser beam.

The first reflector 22, the active layer 23, the second reflector 24, the contact layer 25, the first electrode layer 26 and the second electrode layer 27 may be formed from the group selected from GaAs, AlGaAs, AlAs, AlInGaAs, InP, InGaAsP which are Groups III-V and II-VI compound semiconductors.

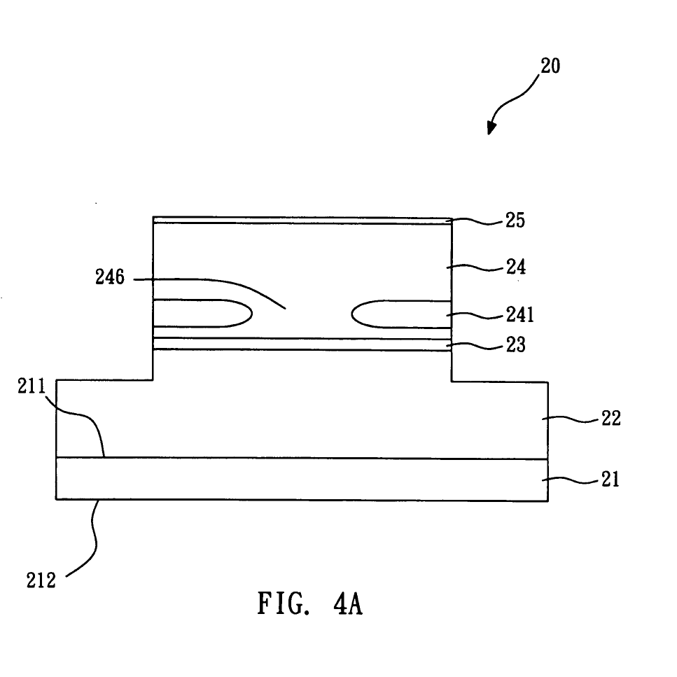

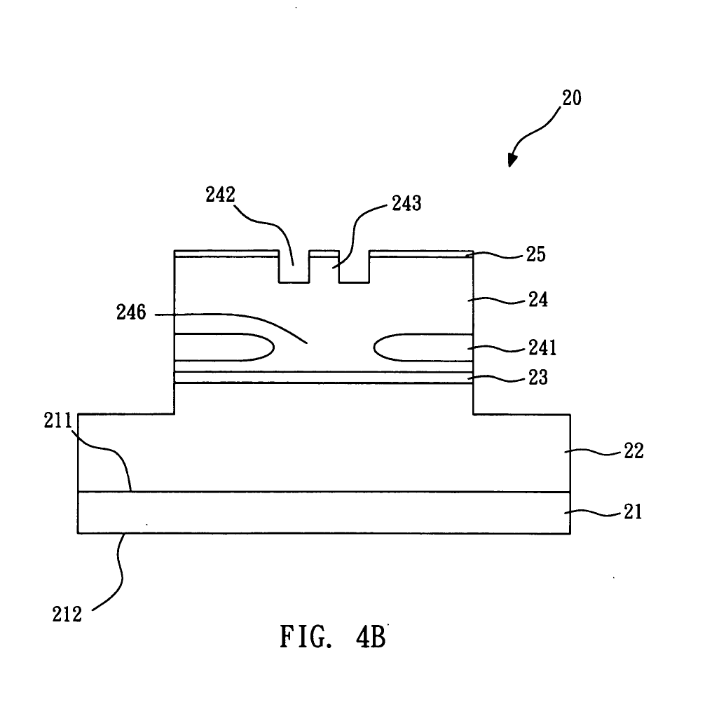

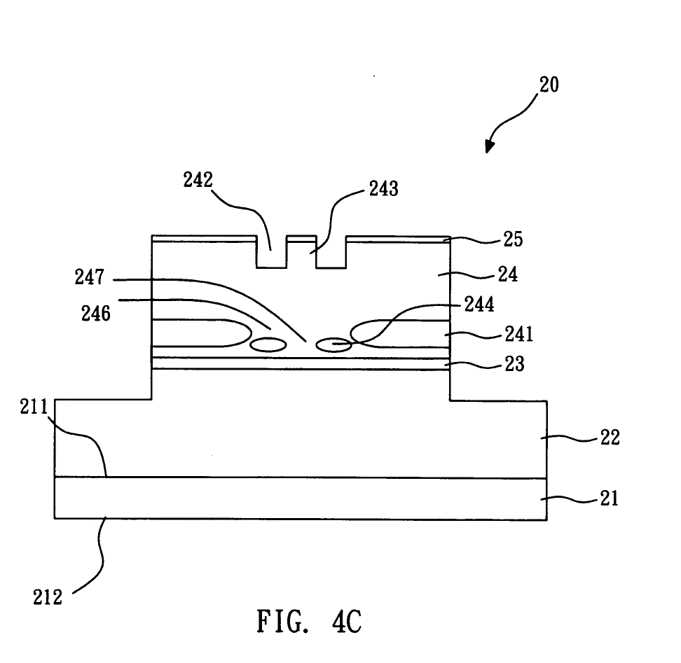

Referring to FIGS. 4A to 4C, they illustrate the manufacturing method of the vertical cavity surface emitting laser, according to the invention. Firstly, referring to FIG. 4A, the substrate 21 is provided. The substrate 21 has a first surface 211 and a second surface 212. Then, in sequence the first reflector 22, first reflector 22, the active layer 23, the second reflector 24 and the contact layer 25 are formed on the first surface 211 of the substrate 21. The above layers are formed by MOCVD (Metal Organic Chemical Vapor Deposition) process. The first confinement layer 241 is formed in the second reflector 24. The first confinement layer 241 is formed by a hydrogen ion implanting process or a high temperature and wet oxidized process. Therefore, the first confinement layer 241 may be an ion-implanted layer or an oxide layer

Referring to FIG. 4B, the slot 242 is formed on the second reflector 24 by an etching process utilizing dry air. A central region 243 for emitting light has a diameter ranging from 1 μm to 5 μm. The depth of the slot 242 is ranges from 0.1 μm to 3 μm.

Referring to FIG. 4C, the second confinement layer 242 is formed by implanting oxygen ion into the second reflector 24 and heating to let the oxygen ion and Al content in the second reflector 24 react to form an oxide layer. The oxygen ion is implanted into the second reflector 24 through the slot 242 so as to decrease the depth of the second reflector 24 and lower the implanting energy. The second confinement layer 242 can be used as an optical and electronic confinement layer.

Referring to FIG. 2 again, the first electrode layer 26 is formed on the contact layer 25 by Lift-off technology for coating Cr, AuZn and Au with thickness 10 nm, 100 nm and 100 nm, respectively. Then, the second surface 212 of the substrate 21 is polished. The second electrode layer 27 is formed on the second surface 212 of the substrate 21. The second electrode layer 27 is an n-type metal AuGeNi and Au with thickness 100 nm and 300 nm, respectively. Finally the vertical cavity surface emitting laser 20 is annealed with high temperature 380° C. and the time 30 seconds to decrease the contact resistance between the metal and the semiconductor.

According to the invention, because the second confinement layer 244 is formed by implanting oxygen ion into the second reflector and heating to let the oxygen ion and Al content in the second reflector 24 react to form an oxide layer, the second confinement layer 244 can be used as an optical and electronic confinement layer. Therefore, the width and depth of the second confinement layer 244 can be achieved preciously and easily. Furthermore, the size of the second aperture 247 can be controlled precisely so as to control the current passed through the second aperture 247.

While an embodiment of the present invention has been illustrated and described, various modifications and improvements can be made by those skilled in the art. The embodiment of the present invention is therefore described in an illustrative, but not restrictive, sense. It is intended that the present invention may not be limited to the particular forms as illustrated, and that all modifications which maintain the spirit and scope of the present invention are within the scope as defined in the appended claims.

What is claimed is:

1. A vertical cavity surface emitting laser, comprising:
a substrate, having a first surface and a second surface;
a first reflector, formed on the first surface of the substrate;
an active layer, formed on the first reflector;
a second reflector, formed on the active layer, the second reflector having a first confinement layer and a second confinement layer, the first confinement layer having a first aperture, the second confinement layer having a second aperture, the second aperture being smaller than the first aperture;
a first electrode layer, formed on the second reflector; and
a second electrode layer, formed on the second surface of the substrate.

2. The vertical cavity surface emitting laser according to claim 1, wherein the second reflector further comprises a slot corresponding to the shape of the second confinement layer.

3. The vertical cavity surface emitting laser according to claim 2, wherein the slot is formed as a circular shape.

4. The vertical cavity surface emitting laser according to claim 1, wherein the first confinement layer is an ion-implanted layer.

5. The vertical cavity surface emitting laser according to claim 1, wherein the first confinement layer is an oxide layer.

6. The vertical cavity surface emitting laser according to claim 1, wherein the second confinement layer is an oxide layer.

7. The vertical cavity surface emitting laser according to claim 1, further comprising a contact layer disposed between the second reflector and the first electrode layer.

8. A method for fabricating a vertical cavity surface emitting laser, comprising the steps of:
(a) providing a substrate, the substrate having a first surface and a second surface;
(b) forming a first reflector on the first surface of the substrate;
(c) forming an active layer on the first reflector;
(d) forming a second reflector on the active layer,;
(e) forming a first confinement layer in the second reflector, the first confinement layer having a first aperture;
(f) forming a second confinement layer in the second reflector, the second confinement layer having a second aperture, the second aperture being smaller than the first aperture;
(g) forming a first electrode layer on the second reflector; and
(h) forming a second electrode layer on the second surface of the substrate.

9. The method according to claim 8, further comprising forming a slot on the second reflector by an etching process after the step (e).

10. The method according to claim 9, wherein the step (f) comprises the steps of:
(f1) implanting oxygen ion into the second reflector;
(f2) heating to let the oxygen ion and Al content in the second reflector react to form an oxide layer.

11. The method according to claim 8, wherein in the step (e) the first confinement layer is formed by a hydrogen ion implanting process.

12. The method according to claim 8, wherein in the step (e) the first confinement layer is formed by a high temperature and wet oxidized process.

13. The method according to claim 8, further comprising forming a contact layer on the second reflector after the step (d).
